(19) United States
(12) Patent Application Publication
(10) Pub. No.: US 2013/0270227 A1
(43) Pub. Date: Oct. 17, 2013

(54) LAYER-LAYER ETCH OF NON VOLATILE MATERIALS

(71) Applicants: Joydeep GUHA, Fremont, CA (US); Jeffrey MARKS, Saratoga, CA (US); Butsurin JINNAI, Mountain View, CA (US)

(72) Inventors: Joydeep GUHA, Fremont, CA (US); Jeffrey MARKS, Saratoga, CA (US); Butsurin JINNAI, Mountain View, CA (US)

(73) Assignee: Lam Research Corporation, Fremont, CA (US)

(21) Appl. No.: 13/446,778

(22) Filed: Apr. 13, 2012

(51) Int. Cl. C23F 1/02; H01L 21/306

(52) U.S. Cl. 216/51; 216/41; 156/345.52; 156/345.26

(57) ABSTRACT

A method for etching a metal layer dispose below a mask is provided. The metal layer is placed in an etch chamber. A precursor gas is flowed into the etch chamber. The precursor gas is adsorbed into the metal layer to form a precursor metal complex. The precursor metal complex is heated to a temperature above a vaporization temperature of the precursor metal complex, while the metal layer is exposed to the precursor gas. The vaporized precursor metal complex is exhausted from the etch chamber.

### BACKGROUND OF THE INVENTION

The present invention relates to etching a layer of non volatile materials through a mask during the production of a semiconductor device. More specifically, the present invention relates to etching a metal containing layer.

During semiconductor wafer processing, features may be etched through a metal containing layer. In the formation of magnetoresistive random-access memory (MRAM) or resistive random-access memory (RRAM) devices, a plurality of thin metal layers or films may be sequentially etched.

### SUMMARY OF THE INVENTION

To achieve the foregoing and in accordance with the purpose of the present invention, a method for etching a metal layer dispose below a mask is provided. The metal layer is placed in an etch chamber. A precursor gas is flowed into the etch chamber. The precursor gas is adsorbed into the metal layer to form a precursor metal complex. The precursor metal complex is heated to a temperature above a vaporization temperature of the precursor metal complex, while the metal layer is exposed to the precursor gas. The vaporized precursor metal complex is exhausted from the etch chamber.

In another manifestation of the invention, an apparatus for etching a metal layer on a substrate is provided. A chamber is provided. A substrate support is provided within the chamber. A gas source is provided to flow a precursor gas into the chamber. An exhaust system is provided for removing gas from the chamber. A heat source is provided for heating the metal layer, wherein the heat source heats the metal layer more than the substrate.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of an embodiment of the invention.

FIGS. 2A-D are schematic views of a stack processed according to an embodiment of the invention.

FIG. 3 is a schematic view of an etch reactor that may be used for etching.

FIG. 4 illustrates a computer system, which is suitable for implementing a controller used in embodiments of the present invention.

FIG. 5 is schematic view of a stack with a plurality of metal layers to be sequentially etched.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

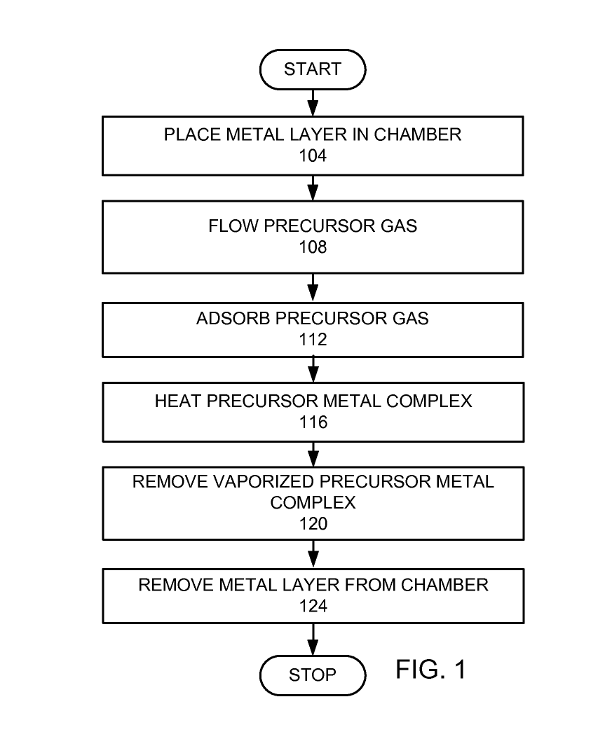

To facilitate understanding, FIG. 1 is a high level flow chart of a process used in an embodiment of the invention. A substrate with a metal layer is placed in a chamber (step 104). A precursor gas is flowed into the chamber (step 108). The precursor gas is adsorbed into the metal layer, forming a precursor metal complex (step 112). The precursor metal complex is heated causing the precursor metal complex to be vaporized (step 116). The vaporized precursor metal complex is exhausted from the chamber (step 120). The substrate and remaining metal layer are removed from the chamber (step 124).

### EXAMPLES

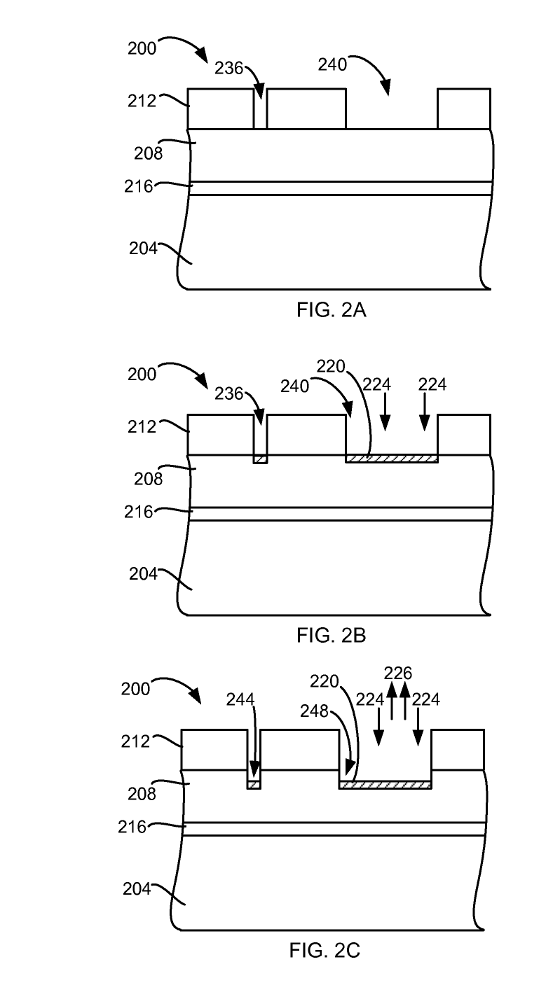

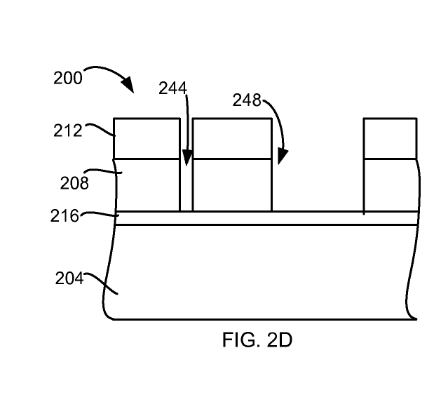

In an example of the invention, a substrate with a metal layer is placed in a plasma processing chamber (step 104). FIG. 2A is a cross-sectional view of a stack 200 with a substrate 204 over which a metal layer 208 has been formed. A patterned thermal hardmask layer 212 is placed over the metal layer 208. In this example, an intermediate layer 216 is placed between the substrate 204 and the metal layer 208. One or more layers may be placed between the substrate 204 and the metal layer 208. In addition, one or more layers may be placed between the patterned thermal hardmask layer 212 and the metal layer 208. In this example, the patterned thermal hardmask layer 212 has features 236, 240 with different aspect ratios. A patterned photoresist mask may be placed above the patterned thermal hardmask layer 212. In this example, the substrate 204 is a silicon wafer, and the metal layer 208 is iron (Fe). Additional metal layers may be used to form magnetoresistive random-access memory (MRAM) or a resistive random-access memory (RRAM) device. The intermediate layer 216 may be one or more additional layers used to form MRAM or RRAM devices. The patterned thermal hardmask layer 212 may be a conventional hardmask material such as SiN or may be another material. The patterned thermal hardmask layer 212 must be resistant to ashing or melting at temperatures at which a precursor metal complex would vaporize. Because of this, the patterned thermal hardmask layer 212 would not be formed from a photoresist material, which melts at a temperature below 300° C.

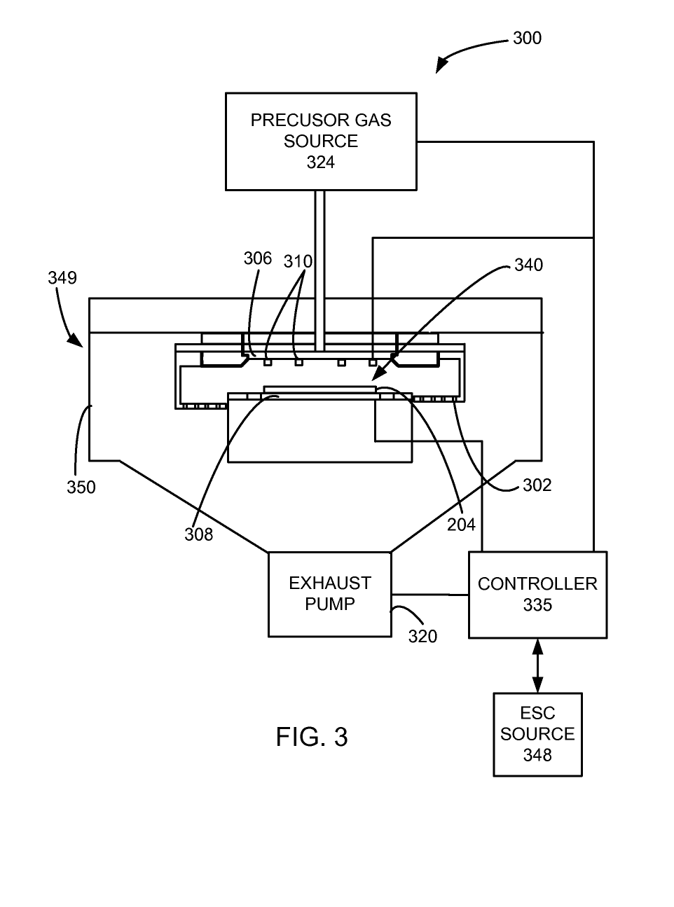

FIG. 3 is a schematic view of an etch reactor that may be used in practicing the invention. In one or more embodiments of the invention, an etch reactor 300 comprises a gas distribution plate 306 providing a gas inlet and a chuck 308, within an etch chamber 349, enclosed by a chamber wall 350. Within the etch chamber 349, the substrate 204 is positioned on top of the chuck 308. The chuck 308 may provide a bias from the ESC source 348 as an electrostatic chuck (ESC) for holding the substrate 204 or may use another chucking force to hold the substrate 204. A heat source 310, such as heat lamps, is provided to heat the metal layer. A precursor gas source 324 is connected to the etch chamber 349 through the distribution plate 306.

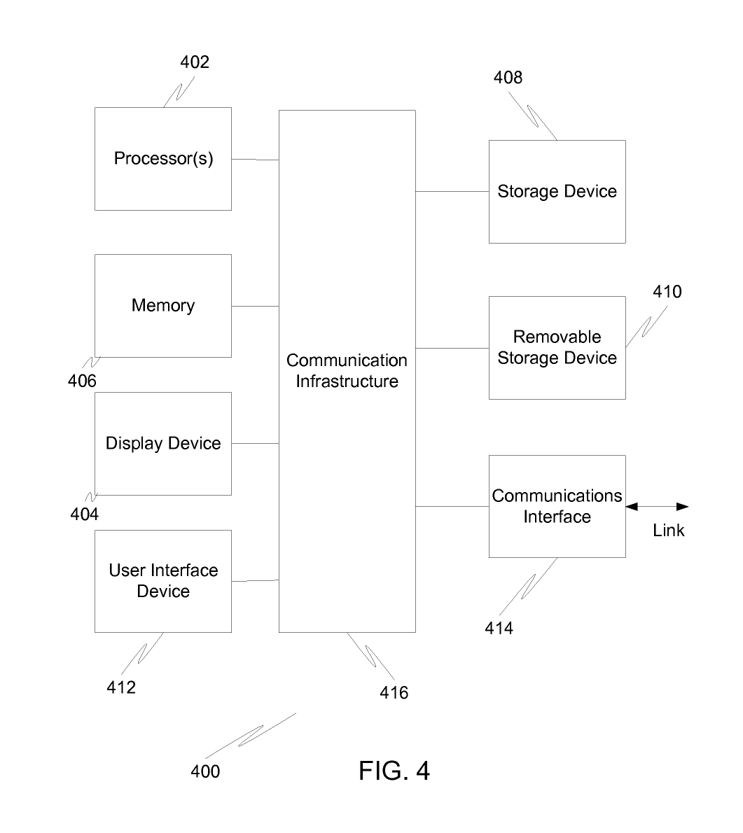

FIG. 4 is a high level block diagram showing a computer system 400, which is suitable for implementing a controller 335 used in embodiments of the present invention. The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

A precursor gas source 324 supplies the precursor gas into interior region 340 of the etch chamber 349 during the etch processes. In this example, the precursor gas is chlorine (Cl₂). The precursor gas is adsorbed into the metal layer to form precursor metal complex. In this example, iron adsorbs chlorine to form Anhydrous iron(III) chloride in the reaction:

2Fe(s)+3Cl₂(g)→2FeCl₃(s).

FIG. 2B is a cross sectional view of the stack 200 after chlorine has been absorbed by iron in the metal layer 208 to form a precursor metal complex 220. Arrows 224 indicate that Cl₂ flows to the metal layer 208 to be adsorbed by the metal layer 208.

The precursor metal complex 220 is heated, which causes the precursor metal complex 220 to vaporize (step 116). In this embodiment, the heat source 310 heats the precursor metal complex to a temperature equal to or greater than the boiling or vaporization point of the precursor metal complex. For FeCl₃ this is about 315° C. In this example, the heat lamps of the heat source 310 heat the precursor metal complex to a temperature of about 400° C. More specifically, in this example, the heat lamps heat the top surface of the precursor metal complex more than the remaining metal layer or substrate. The patterned thermal hardmask layer 212 is preferably of a material that does not melt at 400° C.

The vaporized precursor metal complex is exhausted from the etch chamber 349 (step 120). The exhaust pump 320 may be used to exhaust the vaporized precursor metal complex. Preferably, flowing the precursor gas (step 108), adsorbing the precursor gas (step 112), vaporizing the precursor metal complex (step 116), and removing the vaporized precursor metal complex (step 120) are preformed simultaneously until the etch is completed. FIG. 2C is a cross-sectional view of the stack 200 during the etching process after features 244, 248 in the metal layer 208 have been partially etched. Arrows 226 show how vaporized precursor metal complex is removed from the metal layer to be exhausted from the etch chamber 349, while simultaneously Cl₂ travels to the metal layer 208 to be adsorbed by the metal layer 208 to form precursor metal complex 220. The simultaneous flowing the precursor gas (step 108), adsorbing the precursor gas (step 112), vaporizing the precursor metal complex (step 116), and removing the vaporized precursor metal complex (step 120) provides a continuous etching until the metal layer etch is completed. FIG. 2D is a cross-sectional view of the stack 200 after the etching process is completed. The flow of the precursor gas and heat from the heat source 310 are stopped. The substrate 204 and etched metal layer 208 are removed from the etch chamber 349 (step 124).

In this embodiment, a plasma is not formed or provided to the etch chamber 349. Instead, an un-ionized gas is used for the etching process. Because of this, in this example, the patterned thermal hardmask layer 212 is not etched by the precursor gas. In addition, since plasma in not used, a low pressure and some other plasma parameters are not needed, providing a simpler and faster etching process.

In addition, plasma etching processes for etching metal layers rely on sputtering by energetic ions that form non-volatile byproducts. These non-volatile byproducts deposit on the chamber walls or other parts of the wafer, which may provide contamination. Even if in plasma processing a chemistry is found for etching a metal layer to form volatile metal products, the plasma may breakdown the volatile metal products to non-volatile daughter products, which may deposit on and contaminate the chamber or wafer. This embodiment of the invention provides volatile byproducts in etching a metal layer and in addition does not use a plasma, which prevents the breakdown of volatile byproducts to non-volatile daughter products.

This embodiment of the invention also provides layer by layer control of material etch. In a plasma etch using sputtering, the bombarding ions may have sufficient energy to etch all layers, so that there is no discrimination between different layers. Because this embodiment of the invention does not use bombardment, but chemistry and vaporization temperatures of resulting complexes to etch one layer may be a complete etch stop for another layer. This is more useful in etching very thin films of the order of less than 10 Å, which are typically found in MRAM and RRAM devices and similar technology stacks.

Since flowing the precursor gas (step 108), adsorbing the precursor gas (step 112), vaporizing the precursor metal complex (step 116), and removing the vaporized precursor metal complex (step 120) are preformed simultaneously, the etching is continuous and is faster than a process that provides steps sequentially, which would provide an intermittent etch process.

Using heat lamps to provide heat directly to the top surface of the metal layer provides maximum heat to the precursor metal complex, while minimizing heat to other parts of the stack. Such heating provides additional control of the heating process. Pulsing the heat lamps uses frequency, duty cycle, and other pulse parameters to provide additional control. In other embodiments, the heat lamps may be placed outside of the chamber providing heat through a window. In another embodiment, the heat is collimated to provide a more directional etch. Preferably, the heat source preferentially heats the etch layer with respect to the substrate. More preferably, the heat source preferentially heats the exposed surfaces of the etch layer with respect to the remaining etch layer.

Generally, the precursor gas would be a gas that provides a component that would be adsorbed by the metal layer to be etched to form a precursor metal complex with a sufficiently low vaporization temperature to be vaporized without melting the thermal hardmask or other layers. Preferably, the precursor gas has a halogen containing component, NO, or CO. Preferably, the halogen containing component is PF₃, Cl₂, or SF₆.

Different metals that may be etched are, for example but not limited to, iron (Fe), cobalt (Co), ruthenium (Ru), platinum (Pt), manganese (Mn), palladium (Pd), iridium (Jr), magnesium (Mg), and tantalum (Ta). Different materials for the thermal hardmask may be, for example but not limited to, silicon oxide, tungsten, tantalum, titanium nitride, tantalum nitride, and tungsten nitride. The thermal hardmask should be a different material than the metal layer being etched.

Other embodiments of the invention may use a plasma to create the precursor gas. However, the creation of the volatile byproduct is not through the use of a plasma, but instead the heating of the precursor metal complex to vaporize the precursor metal complex.

Preferably, the heat source heats the precursor metal complex to a temperature of at least 300° C. More preferably, the heat source heats the precursor metal complex to a temperature of between 300° C. to 400° C.

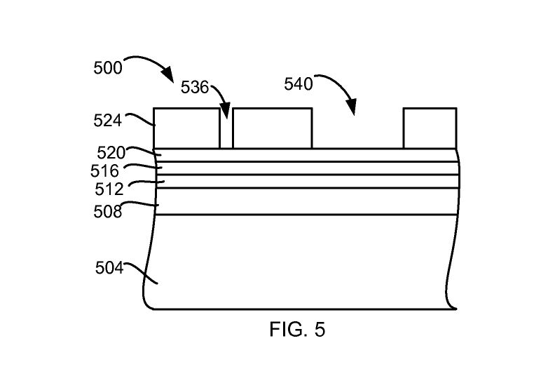

FIG. 5 is a schematic cross-sectional view of part of a stack that may be used in forming an MRAM device. In this example, a substrate 504 is provided. Over the substrate is one or more intermediate layers 508. Over the one or more intermediate layers 508 is a synthetic antiferomagnet (SAF) stack formed by a first cobalt layer 512, a ruthenium layer 516, and a second cobalt layer 520. A thermal hardmask 524 is placed over the second cobalt layer 520. In this example, the ruthenium layer 516 has a thickness of 6 Å to 8 Å. The thickness of the cobalt layers would be 20 Å. The recipe and precursor gas for etching the ruthenium layer 516 would be different than the recipe and precursor gas for etching the cobalt layers 512, 520. Because the recipes for etching the ruthenium and cobalt are different, the etching of one layer is etch stopped by the next layer, since the invention provides highly selective etch processes.

While this invention has been described in terms of several preferred embodiments, there are alterations, permutations, modifications, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for etching a metal layer dispose below a mask, comprising:
placing the metal layer in an etch chamber;
flowing a precursor gas into the etch chamber;
adsorbing the precursor gas into the metal layer to form a precursor metal complex;
heating the precursor metal complex to a temperature above a vaporization temperature of the precursor metal complex, while the metal layer is exposed to the precursor gas; and
exhausting the vaporized precursor metal complex from the etch chamber.

2. The method, as recited in claim 1, wherein the heating the precursor metal complex heats the precursor metal complex to a temperature above 300° C.

3. The method, as recited in claim 2, wherein the precursor gas is a gas comprising a halogen containing component, NO, or CO.

4. The method, as recited in claim 3, wherein the metal layer comprises at least one of iron (Fe), cobalt (Co), ruthenium (Ru), platinum (Pt), manganese (Mn), palladium (Pd), iridium (Ir), magnesium (Mg), and tantalum (Ta).

5. The method, as recited in claim 4, wherein the halogen containing component is at least one of PF₃, Cl₂, or SF₆.

6. The method, as recited in claim 5, wherein the heating the precursor metal complex comprises directing IR radiation to the precursor metal complex.

7. The method, as recited in claim 6, wherein the IR radiation is pulsed, and further comprising using duty cycle to control the IR radiation.

8. The method, as recited in claim 7, wherein the mask is at least one of silicon oxide, tungsten, tantalum, titanium nitride, tantalum nitride, and tungsten nitride.

9. The method, as recited in claim 8, wherein the flowing the precursor gas, the adsorbing the precursor gas, the heating the precursor metal complex, and the exhausting the vaporized precursor metal complex occur simultaneously.

10. The method, as recited in claim 1, wherein the precursor gas is a gas comprising a halogen containing component, NO, or CO.

11. The method, as recited in claim 10, wherein the halogen containing component is at least one of PF₃, Cl₂, or SF₆.

12. The method, as recited in claim 1, wherein the metal layer comprises at least one of iron (Fe), cobalt (Co), ruthenium (Ru), platinum (Pt), manganese (Mn), palladium (Pd), iridium (Jr), magnesium (Mg), and tantalum (Ta).

13. The method, as recited in claim 1, wherein the heating the precursor metal complex comprises directing IR radiation to the precursor metal complex.

14. The method, as recited in claim 13, wherein the IR radiation is pulsed, and further comprising using duty cycle to control the IR radiation.

15. The method, as recited in claim 1, wherein the mask is at least one of silicon oxide, tungsten, tantalum, titanium nitride, tantalum nitride, and tungsten nitride.

16. The method, as recited in claim 1, wherein the flowing the precursor gas, the adsorbing the precursor gas, the heating the precursor metal complex, and the exhausting the vaporized precursor metal complex occur simultaneously.

17. An apparatus for etching a metal layer on a substrate, comprising:
a chamber;
a substrate support within the chamber;
a gas source for flowing a precursor gas into the chamber;
an exhaust system for removing gas from the chamber; and
a heat source for heating the metal layer, wherein the heat source heats the metal layer more than the substrate.

18. The apparatus, as recited in claim 17, further comprising a controller controllably connected to the gas source and the heat source, comprising:
at least one processor; and
computer readable media, comprising:
computer readable code for flowing precursor gas from the gas source into the chamber, wherein the precursor gas is adsorbed by the metal layer to form a precursor metal complex; and
computer readable code to simultaneously provide power to the heat source to cause the precursor metal complex to be heated to a temperature that vaporizes the precursor metal complex.

19. The apparatus, as recited in claim 17, wherein the heat source comprises at least one heat lamp positioned to irradiate an exposed surface of the metal layer.
